(19) United States
(12) Patent Application Publication
(10) Pub. No.: US 2006/0093740 A1
(43) Pub. Date: May 4, 2006

(54) Method and device for manufacturing nanofilter media

(75) Inventors: Seok-Joo Park, Daejeon (KR); Si-Hyun Lee, Daejeon (KR); Soon-Kwan Jeong, Daejeon (KR); Hyun-Seol Park, Daejeon (KR); Ho-Kyung Choi, Daejeon (KR); Young-Joon Rhim, Daejeon (KR)

Correspondence Address: BARDMESSER LAW GROUP, P.C., 910 17TH STREET, N.W., SUITE 800, WASHINGTON, DC, 20006, US

(73) Assignee: Korea Institute of Energy Research, Daejeon (KR)

(21) Appl. No.: 11/264,099

(22) Filed: Nov. 2, 2005

(30) Foreign Application Priority Data
Nov. 2, 2004 (KR) 2004-0088396

(51) Int. Cl. C23C 16/00; B05D 1/08; B29C 71/04

(52) U.S. Cl. 427/248.1; 427/532; 427/446; 118/715

(57) ABSTRACT

A method of manufacturing nanofilter media includes feeding catalyst nanoparticles into a reactor to attach the catalyst nanoparticles to microfilter media located in the reactor and serving as a substrate; feeding a source gas and a reactive gas onto the catalyst nanoparticles; and heating the reactor to synthesize and grow, in the reactor, from the catalyst nanoparticles, any of nanotubes and nanofibers, to obtain a nanofilter media composed of the nanotubes or nanofibers.

### CROSS-REFERENCE TO RELATED APPLICATIONS

This application claims priority to Korean Patent Application No. 2004-0088396, filed on Nov. 2, 2004, which is incorporated by reference herein in its entirety.

### BACKGROUND OF THE INVENTION

1. Field of the Invention

The present invention relates to a method of manufacturing nanofilter media, which are porous media composed of nanotubes or nanofibers formed on a conventional microfilter media that serves as a substrate, by directly synthesizing and growing the nanotubes or nanofibers on the substrate, and to a device for manufacturing the nanofilter media.

2. Description of the Related Art

Nanofilter media obtained by attaching nanofibers to conventional microfilter media are known to improve the filtration efficiency without a large change in the permeability of the filter. The use of the nanofibers to manufacture the filter media results in novel filter media that are advantageous because they cause lower pressure drop while maintaining filtration efficiency equal to that of the conventional microfilter.

Further, filters made from the nanofibers are known to exhibit an excellent ability to filter ultra-fine contaminant particles, known as “nanoparticles.” Where the filter is formed by applying the nanofibers onto the surface of the microfilter media, the fine contaminant particles are collected on the surface of the filter media, and do not infiltrate deep into the region of the microfilter that serves as a substrate, resulting in improved cleaning performance and restorability. As a result, the lifetime of the filter is increased.

Recently, nanofilter media coated with the nanofibers have been manufactured by spinning the nanofibers on the fibrous microfilter that serves as a substrate by using an electrospinning technique. However, since the electrospinning technique works in a top-down manner, where the nanofibers are spun from the polymer solution by applying an electrical field between the capillary end and the substrate, the diameter of the nanofibers cannot be decreased below a particular value (a lower limit).

### SUMMARY OF THE INVENTION

Accordingly, the present invention is directed to a method of manufacturing nanofilter media that substantially obviates one or more of the problems and disadvantages of the related art.

One object of the present invention is to provide a device and method for manufacturing the nanofilter media composed of the nanotubes or nanofibers.

As one embodiment, the method includes directly synthesizing and growing the nanotubes or nanofibers on a microfilter media that serves as a substrate in a bottom-up manner.

In one aspect, there is provided a method of manufacturing nanofilter media that includes feeding catalyst nanoparticles into a reactor to attach the catalyst nanoparticles to microfilter media located in the reactor and serving as a substrate; feeding a source gas and a reactive gas onto the catalyst nanoparticles; and heating the reactor to synthesize and grow, in the reactor, from the catalyst nanoparticles, any of nanotubes and nanofibers, to obtain a nanofilter media composed of the nanotubes or nanofibers.

In another aspect, a device for manufacturing nanofilter media includes a reactor having a microfilter media therein, the microfilter media serving as a substrate on which any of nanotubes and nanofibers are formed; a unit for supplying catalyst nanoparticles into the reactor; a gas feeding unit for feeding a source gas and a reactive gas into the reactor; and a heater for heating the reactor.

Additional features and advantages of the invention will be set forth in the description that follows, and in part will be apparent from the description, or may be learned by practice of the invention. The advantages of the invention will be realized and attained by the structure particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE ATTACHED FIGURES

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a flowchart schematically showing the process of manufacturing nanofilter media, according to one embodiment of the present invention;

FIG. 2 shows the process of heating catalyst nanoparticles attached to a fibrous or fabric microfilter, according to one embodiment of the present invention;

FIG. 3 shows the process of heating the catalyst nanoparticles attached to a membrane microfilter, according to one embodiment of the present invention;

FIG. 4 shows the synthesis and growth of the nanotubes or nanofibers on the fibrous or fabric microfilter, according to one embodiment of the present invention;

FIG. 5 shows the synthesis and growth of the nanotubes or nanofibers on the membrane microfilter, according to one embodiment of the present invention; and

FIG. 6 shows schematically a device for manufacturing the nanofilter media by synthesizing and growing the nanotubes or nanofibers, according to one embodiment of the present invention.

### DETAILED DESCRIPTION OF THE PREFERRED EMBODIMENTS

Reference will now be made in detail to the preferred embodiments of the present invention, examples of which are illustrated in the accompanying drawings.

A method of manufacturing nanofilter media is provided, which includes loading catalyst nanoparticles into a reactor equipped with a microfilter media that serves as a substrate, so as to attach the catalyst nanoparticles to the microfilter media, feeding a source gas and a reactive gas onto the catalyst nanoparticles, heating the entire reactor (or selectively heating the microfilter media in the reactor, or heating the catalyst nanoparticles attached to the microfilter media in the reactor) to synthesize and grow nanotubes or nanofibers from the heated catalyst nanoparticles, in order to form a nanofilter media that includes the synthesized and grown nanotubes or nanofibers.

The catalyst particles can include, for example, cobalt, nickel, iron, or various alloys thereof. The microfilter can include, for example, a fibrous filter, a fabric filter, or a membrane filter. The material for the microfilter media may include various polymers, silicon oxide (SiO₂), alumina (Al₂O₃), ceramics, or metal oxides.

The catalyst nanoparticles can be prepared using an inert gas condensation (IGC) processes, such as resistance heating, plasma heating, induction heating or laser heating, chemical vapor condensation (CVC) processes using a resistance coil reactor, a flame reactor, a laser reactor or a plasma reactor. Liquid processes, such as direct precipitation, co-precipitation, freeze drying or spray pyrolysis, can also be used.

The catalyst nanoparticles may include a transition metal, sulfides, carbides, oxides or salts of the transition metal, or an organic compound containing the transition metal.

The catalyst nanoparticles formed from the transition metal may be prepared from the precursor of the transition metal supported on the microfilter media, and converted into the transition metal through reduction, sintering, sulfurization or carbonization. The catalyst nanoparticles are supported on the microfilter media using painting, dipping, spraying or deposition.

The catalyst nanoparticles formed of the metal sulfide may include metal sulfide obtained by sulfurizing the catalyst nanoparticles of the transition metal with hydrogen sulfide (H₂S) or thiophene. In addition, the catalyst nanoparticles formed of the metal sulfide may include nanoparticles formed of a solid particulate mixture comprising the transition metal and sulfur. Furthermore, the catalyst nanoparticles formed of the metal sulfide may include nanoparticles in the form of droplets comprising an ionic solution of the transition metal and sulfur.

The catalyst nanoparticles formed of the organic compound may include nanoparticles in the form of droplets comprising the catalyst precursor in the form of nanodroplets.

The source gas may include a hydrocarbon gas or a silane gas, depending on the material used to manufacture nanotubes or nanofibers.

The reactive gas may include an inert gas, hydrogen gas, oxygen gas, or mixtures thereof, and may further include a co-catalyst such as hydrogen sulfide (H₂S) or thiophene, if required.

The inert gas may include helium (He) gas or argon (Ar) gas to transport the catalyst nanoparticles or to dilute the reactive gas.

The catalyst nanoparticles may be heated using a resistance heater formed of resistance coils. In addition, or alternatively, the catalyst nanoparticles may be heated using microwave radiation, or using electromagnetic induction, or using laser heating, or using radio frequency (RF) heating.

The material for the nanotubes or nanofibers may include carbon, silicon, or silicon oxides.

The nanofilter media may include a filter media formed by synthesizing and growing the nanotubes or nanofibers on a conventional microfilter in a bottom-up manner. In addition, the nanofilter media may include a filter media that can simultaneously collect dust and adsorb gas.

Further, the nanofilter media may include a catalyst filter, an antibiotic filter, or a deodorization filter, able to remove volatile organic compounds (VOCs), sterilize air and perform deodorizing if additional metal nanoparticles are deposited on the nanotubes or nanofibers.

The nanofilter media can have high mechanical strength, and also be able to endure high temperatures, and/or it can be a chemical proof filter media that is resistant to predetermined chemicals.

The catalyst precursor is selected from, for example, ferrocene, iron-pentacarbonyl, dicobalt-octacarbonyl, and nickel-carbonyl.

An exemplary device for manufacturing nanofilter media includes a unit for forming and feeding catalyst nanoparticles, a reactor equipped with microfilter media to which the catalyst nanoparticles are attached, a unit to feed the reactive gas and a source gas into the reactor, and a heater to heat the catalyst nanoparticles in the reactor.

The unit for forming and feeding catalyst nanoparticles includes a catalyst nanoparticle forming portion, and further includes a nanoparticle classification part and/or a concentration controller to control the concentration of the nanoparticles, if required. Also, a vaporous catalyst precursor feeder may be included to feed the precursor of the catalyst nanoparticles in a vapor phase into the reactor.

The reactor can also include a filter holder or a quartz tube in which the microfilter media are placed. In addition or alternatively, the reactor can include a conveyor line through which the microfilter media are continuously transported.

The heater includes a power module to apply current to the resistance heater formed of resistance coils mounted around the reactor. The heater can also include a microwave generator to generate microwaves and a microwave guide connected to the reactor to guide the microwaves. The heater can also include a high frequency coil mounted around the reactor and a power module to apply high frequency current to the high frequency coil. The heater can also include an RF generator mounted around the reactor. The heater can also include a laser generator mounted around the reactor and a lens assembly to concentrate laser light beams generated by the laser generator.

The nanotubes or nanofibers can be synthesized and grown on conventional microfilter media, thereby manufacturing nanofilter media having higher filtration efficiency, in particular, better ability to filter nanoparticles (ultra-fine particles), compared to a conventional microfilter.

Microfilter media having a low pressure drop and low filtration efficiency are used as a substrate, and thus, the nanotubes or nanofibers are appropriately synthesized and grown on the substrate, to manufacture a filter media having lower pressure drop and the filtration efficiency superior to conventional filter media, that is, having a higher filter quality (FQ).

Furthermore, the nanotubes or nanofibers, in particular, carbon nanotubes or carbon nanofibers formed of carbon, are synthesized and grown to manufacture the nanofilter media, which then are formed into chemical filters that can simultaneously adsorb and remove contaminant gas and filter particulate matter.

In addition, the metal nanoparticles can be further deposited on the synthesized nanotubes or nanofibers, thereby manufacturing filter media of a catalyst filter, an antibiotic filter, or a deodorization filter able to remove VOCs, sterilize air, or perform deodorization.

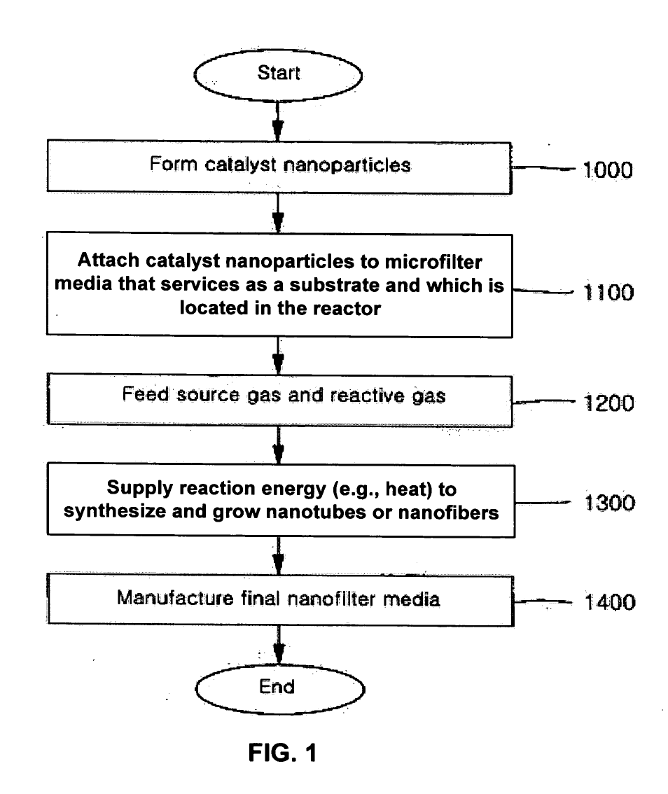

FIG. 1 is a flowchart illustrating an exemplary process of manufacturing the nanofilter media including nanotubes or nanofibers synthesized and grown on a microfilter media that serves as a substrate, according to the present invention.

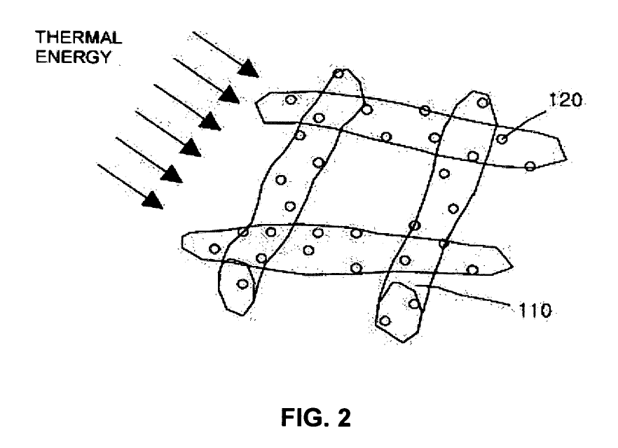

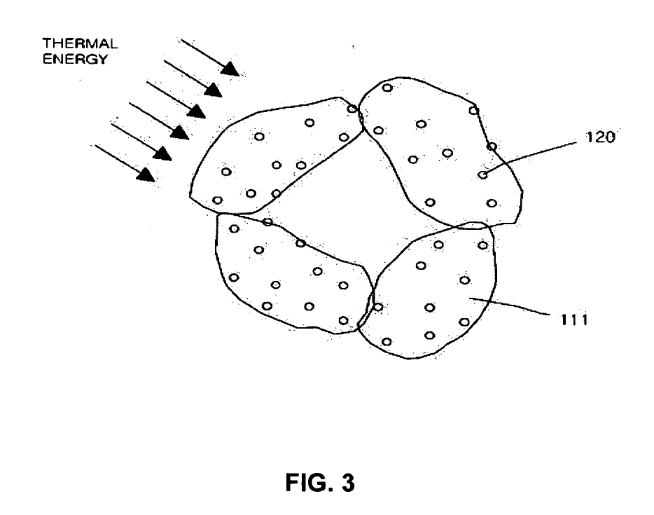

FIGS. 2 and 3 schematically illustrate the heating of the catalyst nanoparticles attached to the surface of the fibrous or fabric microfilter media and the surface of the membrane microfilter media while maintaining appropriate dispersion rates.

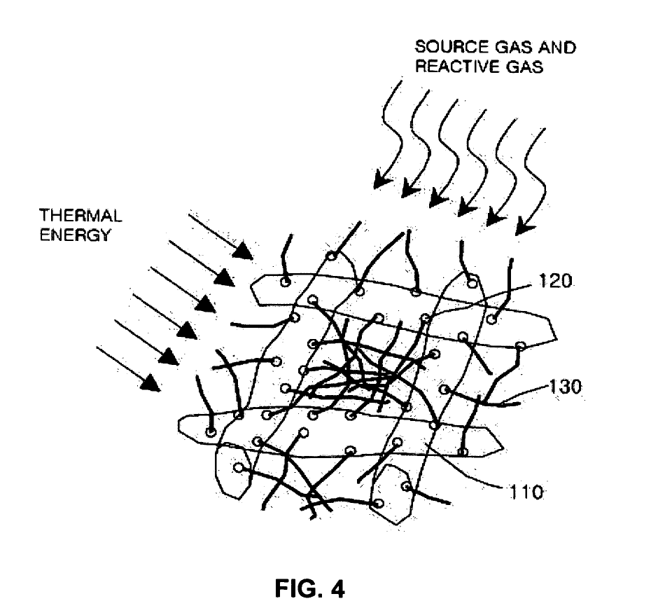

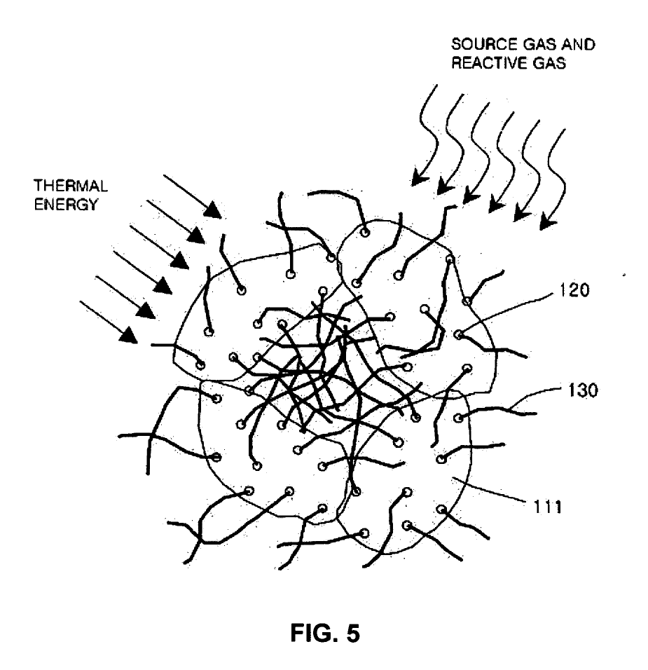

FIGS. 4 and 5 schematically illustrate the synthesis and growth of the nanotubes or nanofibers on the microfilter media, according to one embodiment of the present invention.

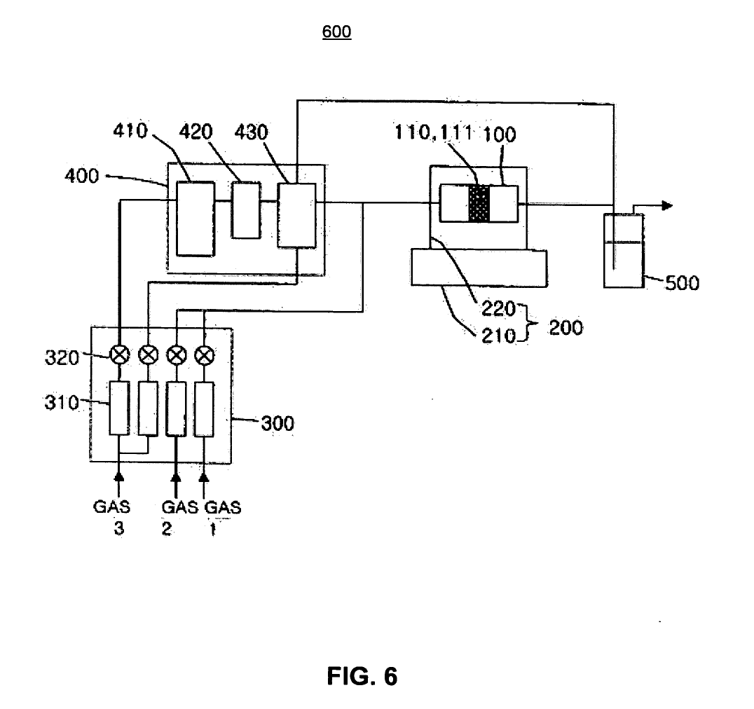

FIG. 6 illustrates a device 600 for manufacturing the nanofilter media including the synthesized and grown nanotubes or nanofibers, according to one embodiment of the present invention.

As shown in FIG. 1, the method of manufacturing the nanofilter media can be performed using the device 600 depicted in FIG. 6. The device 600 shown in FIG. 6 is used to implement the preparation of the nanofilter media by synthesizing and growing the nanotubes or nanofibers from the catalyst nanoparticles attached to the microfilter media that serves as a substrate.

Referring to FIGS. 2, 3 and 6, a device 600 for manufacturing the nanofilter media according to the present invention includes a reactor 100 of FIG. 6 equipped with microfilter media that serves as a substrate 110 of FIG. 2 or substrate 111 of FIG. 3. The substrate 110 or 111 has catalyst nanoparticles 120 of FIGS. 2 or 3 attached thereto, i.e., the catalyst nanoparticles 120 formed of a transition metal are attached to the surface of the fibrous or fabric microfilter media 110 or the surface of the membrane microfilter media 111. The reactor 100 includes a quartz tube, a filter holder, or a conveyor line to transport the substrate 110 or 111.

In addition, a heater 200 can be included to simultaneously heat the catalyst nanoparticles 120 and the substrate 110 or 111 once it is delivered into the reactor 100, or to selectively heat only the catalyst nanoparticles 120. The heater 200 may be equipped with a microwave generator 210 shown in FIG. 6, to generate microwaves and a microwave guide 220 shown in FIG. 6, to guide the generated microwaves into the reactor 100.

In addition, as shown in FIG. 6, the device 600 includes a gas feeding unit 300 to feed the source gas and the reactive gas required to synthesize the nanotubes or nanofibers into the reactor 100, a unit 400 for forming and feeding catalyst nanoparticles, to form the catalyst nanoparticles 120 and to feed the formed catalyst nanoparticles 120 into the reactor 100, and a discharging unit 500 to treat the gas discharged from the reactor 100.

The gas feeding unit 300 is provided with a gas bombe to feed the source gas (such as a hydrocarbon gas or a silane gas), the reactive gas (such as hydrogen sulfide gas), the co-catalyst gas (such as thiophene), the reducing gas (such as hydrogen gas), the oxidizing gas (such as oxygen), and the carrier gas (such as an inert gas) into the reactor 100. In addition, the gas feeding unit 300 further can include a mass flow controller (MFC) 310, mounted on a pipe line between the gas bombe and the reactor 100 and/or the unit 400 that forms and feeds catalyst nanoparticles, to control the amount of gas fed into the reactor 100. The mass flow controller 310 can also include an on/off valve 320. Multiple such gas bombes, MFCs 310, and the on/off valves 320 may be provided, if necessary.

As shown in FIGS. 2 and 3, the catalyst nanoparticles 120 are provided in the form of a transition metal, a precursor of the transition metal, or a mixture comprising transition metal and the co-catalyst component (such as sulfur) on the substrate 110 or 111. To this end, the unit 400, which is connected to the reactor 100, is provided. The unit 400 for forming and feeding catalyst nanoparticles may be operated using any process able to feed the solid catalyst or liquid catalyst or catalyst precursor nanoparticles in the form of an aerosol.

In addition, the unit 400 includes a catalyst nanoparticle forming portion 410, and a catalyst nanoparticle classification portion 420 and/or a concentration controlling portion 430 to control the concentration of the catalyst nanoparticles, if necessary.

An exemplary process of manufacturing the nanofilter media is depicted in FIG. 1, and can use the device 600 for manufacturing the nanofilter media, the catalyst nanoparticles 120 are first formed at step 1000 of FIG. 1.

Any known process of forming the catalyst nanoparticles can be used, including all the known processes of synthesizing nanoparticles, any modified processes of synthesizing the nanoparticles, or combinations thereof. For example, such known processes include IGC. CVC, aerosol spraying, etc.

The formed catalyst nanoparticles 120 may be supplied in solid or liquid phase. The material for the catalyst nanoparticles 120 can include a pure transition metal, a transition metal compound, a transition metal precursor, or a transition metal compound containing the sulfur.

As shown in FIG. 6, the catalyst nanoparticles 120 formed using the catalyst nanoparticle forming portion 410 may be fed into the reactor 100 without changes.

In addition, the catalyst nanoparticles 120 formed using the catalyst nanoparticle forming portion 410 may be classified or selected based on having a desired diameter, using the nanoparticle classification portion 420, and then fed into the reactor 100, if required.

In addition, the catalyst nanoparticles 120 formed using the catalyst nanoparticle forming portion 410 may be further mixed with the source gas, the reactive gas or the mixture gas thereof, using a concentration controller 430 to control the concentration of the nanoparticles, and discharged while the concentration of the catalyst nanoparticles 120 is controlled, and then fed into the reactor 100, if required.

Thus, the catalyst nanoparticles 120 formed using the nanoparticle forming and feeding unit 400 are fed into the reactor 100, and subsequently, attached to the microfilter media in the reactor 100, at step 1100 of FIG. 1.

In addition, the substrate 110 or 111 to which the catalyst nanoparticles 120 have been previously attached, may be provided into the reactor 100.

In addition, the catalyst nanoparticles 120 formed using the catalyst nanoparticle forming portion 410 may be classified (selected) according to a desired diameter using the nanoparticle classification portion 420, and the selected catalyst nanoparticles may be attached to the substrate 110 or 111 in the reactor 100.

In addition, the catalyst nanoparticles 120 formed using the catalyst nanoparticle forming portion 410, or the catalyst nanoparticles 120 selected using the nanoparticle classification portion 420 may be fed into the reactor 100 while their concentration is controlled by the source gas, the reactive gas or the mixture gas, which is (are) also fed through the concentration controller 430 to control the concentration of the nanoparticles, and thus, may be attached to the substrate 110 or 111.

After the nanoparticles 120 are prepared for attachment to the microfilter media while maintaining a predetermined distribution range in the reactor 100, the source gas or the reactive gas is fed into the reactor 100 at step 1200 of FIG. 1.

The source gas is selected depending on the material for nanotubes or nanofibers 130 which are synthesized and grown on the substrate 110 or 111. For example, to synthesize carbon nanotubes or carbon nanofibers, a hydrocarbon gas, such as acetylene gas, methane gas, propane gas or benzene may be used as the source gas.

The reactive gas can include a co-catalyst gas, a reducing gas, an oxidizing gas, a carrier gas, or mixtures thereof.

As such, the co-catalyst gas is an adjuvant catalyst used to accelerate the synthesis and growth of the nanotubes or nanofibers 130 from the catalyst nanoparticles 120 as shown in FIG. 4, and is exemplified by hydrogen sulfide (H₂S) gas and thiophene vapor. The hydrogen sulfide gas and the thiophene vapor react with the catalyst nanoparticles 120 of the transition metal while a certain amount of thermal energy is supplied to the reactor 100, so that the catalyst nanoparticles 120 are converted into catalyst nanoparticles of transition metal sulfide. This lowers the melting point of the catalyst nanoparticles 120.

Since the temperature required to synthesize and grow the nanotubes or nanofibers 130 can be lowered using the catalyst nanoparticles 120 of the transition metal sulfide, which has a low melting point, deformation and breakage due to deterioration of the substrate is avoided.

The reducing gas functions to reduce the catalyst nanoparticles 120 of the transition metal that have been previously oxidized, while a predetermined thermal energy is supplied to the reactor 100, and is exemplified by hydrogen gas.

The oxidizing gas may be used for oxidation of a product or of a by-product in the reactor 100 during or after synthesis, if required.

The carrier gas is fed into the reactor 100 along with the above gases, and therefore controls the concentration of the above gases or the flow rate of gas in the reactor 100, if required. Such a carrier gas includes, for example, an inert gas (e.g., helium or argon), or a nitrogen gas.

Subsequently, the thermal energy is supplied to the substrate 110 or 111 in the reactor 100, to the catalyst nanoparticles 120, or to the source gas and the reactive gas to synthesize and grow the nanotubes or nanofibers 130 from the catalyst nanoparticles 120 that are attached to the substrate 110 or 111 as shown in FIGS. 3 and 4 in step 1300 of FIG. 1.

The substrate 110 or 111 in the reactor 100, the catalyst nanoparticles 120, or the source gas and the reactive gas may be simultaneously heated, or selectively heated, if necessary.

The heater 200 used to supply the thermal energy to the reactor 100 may be appropriately selected depending on the material of the substrate 110 or 111 in the reactor 100, that is, depending on whether or not the substrate 110 or 111 needs to be protected from heat.

Such a heater 200, which supplies the thermal energy to the reactor 100, may include, for example, a resistance coil heater, a microwave radiator, an electromagnetic induction heater, a laser heater, or an RF heater.

The heater 200 may selectively heat the catalyst nanoparticles 120, the substrate 110 or 111, or the source gas and the reactive gas, or may heat the entire reactor 100.

Finally, the nanotubes or nanofibers 130 are synthesized and grown while maintaining the predetermined porous properties of the microfilter media by controlling the process conditions for manufacturing the nanofilter media, including the conditions of the size and the concentration of the catalyst nanoparticles 120, to obtain desired nanofilter media at step 1400 of FIG. 1.

In the nanofilter media, the diameter of the synthesized nanotubes or nanofibers 130 may be controlled by adjusting the size of the catalyst nanoparticles 120. The distribution degree, that is, the density of the nanotubes or nanofibers 130, may be controlled by adjusting the synthesis conditions, such as distribution concentration of the catalyst nanoparticles 120, concentration of the source gas, time periods or temperatures required for synthesis, etc.

As described above, a method and device for manufacturing nanofilter media is provided, in which the catalyst nanoparticles 120 are attached to the microfilter media that serves as a substrate, from which the nanotubes or nanofibers are synthesized in the presence of the source gas and/or the reactive gas while supplying predetermined energy required to induce the synthetic reaction using a predetermined heater. Thereby, the nanofilter media can be obtained by synthesizing and growing the nanotubes or nanofibers from the catalyst nanoparticles in a bottom-up manner.

In the nanofilter media, the diameter and solidity of the nanotubes or nanofibers may be controlled by the size and the numerical concentration of the catalyst nanoparticles 120 attached to the microfilter media, and by controlling other synthesis conditions and parameters.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing nanofilter media, comprising:
feeding catalyst nanoparticles into a reactor to attach the catalyst nanoparticles to microfilter media located in the reactor;
feeding a source gas and a reactive gas onto the catalyst nanoparticles; and
heating the reactor to form, in the reactor, from the catalyst nanoparticles, any of nanotubes and nanofibers on the microfilter media, to obtain a nanofilter media composed of the nanotubes or nanofibers.

2. The method of claim 1, wherein the microfilter media comprises any of a fibrous filter, a fabric filter, and a membrane filter.

3. The method of claim 1, wherein the microfilter media comprises any of a polymer, silicon oxide, alumina, ceramics, and metal oxides.

4. The method of claim 1, wherein the catalyst nanoparticles are prepared using inert gas condensation processes and including any of resistance heating, plasma heating, induction heating, and laser heating.

5. The method of claim 1, wherein the catalyst nanoparticles are prepared using a chemical vapor condensation processes that includes any of resistance coil reactor, a flame reactor, a laser reactor and a plasma reactor.

6. The method of claim 1, wherein the catalyst nanoparticles are prepared using a liquid processes that includes any of direct precipitation, co-precipitation, freeze drying, and spray pyrolysis.

7. The method of claim 1, wherein the catalyst nanoparticles comprise any of a transition metal, a sulfide, a carbide, an oxide, a salts of the transition metal, and an organic compound containing the transition metal.

8. The method of claim 7, wherein the catalyst nanoparticles formed of the transition metal comprise the transition metal converted from a transition metal precursor, which is supported on the microfilter media that serves as a substrate, through reduction, sintering, sulfurization or carbonization.

9. The method of claim 7, wherein the catalyst nanoparticles formed of the metal sulfide comprise metal sulfide formed by sulfurizing the catalyst nanoparticles of the transition metal with hydrogen sulfide (H₂S) or thiophene.

10. The method of claim 7, wherein the catalyst nanoparticles formed of the metal sulfide comprise nanoparticles composed of a solid particulate mixture including the transition metal and sulfur.

11. The method of claim 7, wherein the catalyst nanoparticles formed of the metal sulfide comprise droplet nanoparticles composed of an ionic solution including the transition metal and sulfur.

12. The method of claim 7, wherein the catalyst nanoparticles formed of the organic compound comprise droplet nanoparticles composed of a nanodroplet catalyst precursor.

13. The method of claim 12, wherein the catalyst precursor comprises ferrocene, iron-pentacarbonyl, dicobalt-octacarbonyl, or nickel-carbonyl.

14. The method of claim 1, wherein the catalyst nanoparticles are in any of a solid phase or a liquid phase.

15. The method of claim 1, wherein the attachment of the catalyst nanoparticles is performed by feeding, dispersing and attaching the catalyst nanoparticles onto the microfilter media in the reactor.

16. The method of claim 1, wherein the catalyst nanoparticles are attached by supporting the catalyst nanoparticles on the microfilter media using any of painting, dipping, spraying and deposition, and wherein the microfilter media with the attached catalyst nanoparticles are delivered into the reactor.

17. The method of claim 1, wherein the catalyst nanoparticles are classified by their diameter, and then fed into the reactor.

18. The method of claim 1, wherein the feeding step further comprises controlling concentration of the catalyst nanoparticles.

19. The method of claim 1, wherein the catalyst nanoparticles comprise separate a plurality of different catalysts.

20. The method of claim 1, wherein the catalyst nanoparticles comprise an aggregate in which the catalyst nanoparticles adhere to each other.

21. The method of claim 1, wherein the source gas comprises a carbon source gas that further includes a hydrocarbon gas.

22. The method of claim 1, wherein the source gas comprises a silicon source gas that further includes a silane gas.

23. The method of claim 1, wherein the reactive gas comprises any of a co-catalyst gas, a reducing gas, an oxidizing gas, an inert gas, and mixtures thereof.

24. The method of claim 23, wherein the co-catalyst gas comprises a hydrogen sulfide (H₂S) gas or thiophene vapor.

25. The method of claim 23, wherein the inert gas comprises helium gas or argon gas to transport the catalyst nanoparticles or dilute the reactive gas.

26. The method of claim 1, wherein the nanotubes comprises carbon nanotubes.

27. The method of claim 1, wherein the nanofibers comprise carbon nanofibers.

28. The method of claim 1, wherein the nanofibers comprise silicon (Si) fibers.

29. The method of claim 1, wherein the nanofibers comprise silicon dioxide (SiO₂) fibers.

30. The method of claim 1, wherein the nanofilter media comprises a filter media including the carbon nanotubes synthesized and grown on the microfilter media in a bottom-up manner.

31. The method of claim 1, wherein the nanofilter media comprises a filter media that functions to simultaneously perform dust collection and gas adsorption.

32. The method of claim 1, wherein the nanofilter media comprises a catalyst filter media, an antibiotic filter media, and a deodorization filter media.

33. The method of claim 1, wherein the nanofilter media comprises additional metal nanoparticles deposited onto any of the nanotubes and nanofibers.

34. A device for manufacturing nanofilter media, comprising:
a reactor having a microfilter media therein, the microfilter media serving as a substrate on which any of nanotubes and nanofibers are formed;
a unit for supplying catalyst nanoparticles into the reactor;
a gas feeding unit for feeding a source gas and a reactive gas into the reactor; and
a heater for heating the reactor.

35. The device of claim 34, wherein the reactor further comprises a filter holder in which the microfilter media is located.

36. The device of claim 34, wherein the reactor comprises a quartz tube in which the microfilter media is located.

37. The device of claim 34, wherein the reactor comprises a conveyor line through which the microfilter media is continuously transported.

38. The device of claim 34, wherein the heater comprises any of a resistance coil heater, a microwave radiator, an electromagnetic induction heater, a laser heater, and a radio frequency heater.

39. The device of claim 34, wherein the heater selectively heats any of the catalyst nanoparticles, the substrate, the source gas, the reactive gas, and the entire reactor.
